(19) United States
(12) Patent Application Publication
(10) Pub. No.: US 2026/0300563 A1
(43) Pub. Date: Oct. 1, 2026

(54) HIERARCHICAL PRECISION IN A 3D GAUSSIAN SPLATTING MODEL

(71) Applicant: Adeia Guides Inc., San Jose, CA (US)

(72) Inventors: Ning Xu, Irvine, CA (US); Zhiyun Li, Kenmore, WA (US)

(21) Appl. No.: 19/094,248

(22) Filed: Mar. 28, 2025

(51) Int. Cl. G06F 30/12

(52) U.S. Cl. CPC G06F 30/12

(57) ABSTRACT

Systems and methods are provided for incorporating hierarchical precision in 3D Gaussian Splatting modeling. These methods and systems enable the adaptation of model complexity and quality based on device capacities without requiring multiple separately trained models. In some embodiments, a system comprises a data processing application that accesses data associated with a 3D scene and generates and stores a hierarchical data structure that is used to generate a rendered view of the 3D scene.

### BACKGROUND

This disclosure is related to hierarchical modeling of 3D scenes.

### SUMMARY

Three dimensional (3D) Gaussian Splatting is a model or technique for efficiently creating realistic 3D images, scenes, and animations. 3D Gaussian Splatting (3DGS) may represent a 3D scene using soft-edged splats of light and color, herein referred to as Gaussian Splats (GSs), that are blended together smoothly to represent a scene. The distribution of light that emanates from these GSs are based at least in part on 3D Gaussian functions. By using these overlapping GSs to represent a scene, computers may reduce the need for heavy calculations required by other 3D modeling methods, allowing detailed and complex images to be generated more quickly. Although 3D Gaussian Splatting has emerged as an efficient, high-quality method for real-time rendering, its memory consumption is significant. This constraint makes it challenging to deploy high-quality 3D Gaussian Splatting models on memory-limited devices such as mobile phones, virtual reality (VR) headsets, and other low-power hardware.

To help address these problems, methods and systems are disclosed for incorporating hierarchical precision in a 3D Gaussian Splatting model that can be used, for example, by a variety of computer graphics or rendering devices with different hardware capabilities. These methods and systems enable the adaptation of model complexity and quality based on device capacities without requiring multiple separately trained 3DGS models. In some embodiments, a system (e.g., a system comprising a server for processing 3D data) executes (e.g., using instructions stored in non-transitory memory) a data processing application that accesses data associated with a 3D scene and generates and stores a hierarchical data structure that is used by the system or by other devices to generate a rendered view of the 3D scene.

In some embodiments, the data processing application generates a hierarchical data structure that comprises a base level of the hierarchical data structure and an additional level of the hierarchical data structure. In some embodiments any suitable number of additional levels may also be created. The base level of the hierarchical data structure may comprise a first plurality of GSs, wherein parameters (e.g., position parameters, opacity) for the first plurality of GSs are stored at a first bit depth (i.e., precision). The additional level of the hierarchical data structure may comprise a second plurality of GSs, wherein parameters for the second plurality of GSs may be stored at a second bit depth. The second bit depth may be greater than the first bit depth. For example, at a first level of precision with a bit depth of 8 bits, a parameter value may be 0.10011100. At a higher level of precision with a bit depth of 16 bits (i.e., the second bit depth), for example, the parameter value may be 0.1001110000001001, which begins with the same 8 bits (e.g., 10011100) as the parameter at the first level of precision. The second bit depth may be equal to the first bit depth. The second plurality of GSs may comprise more GSs than the first plurality of GSs. The second plurality of GSs may comprise a subset of GSs that contains a number of GSs equal to a number of GSs in the first plurality of GSs, wherein respective parameters of each GS of the subset of GSs are based at least in part on respective parameters of a respective GS of the first plurality of GSs.

The hierarchical data structure may comprise lower-fidelity models that are contained within higher-fidelity models. For example, a base level (i.e., a lower-fidelity model) of the hierarchical data structure may comprise 250k GSs, wherein at least some parameters (e.g., position, opacity) of the 250k GSs of the base level are stored at a bit depth of 4 bits, and an additional level (i.e., a higher-fidelity model) of the hierarchical data structure may comprise 250k GSs, wherein parameters of the 250k GSs of the additional level are stored at a bit depth of 16 bits. In this example, parameters of the 250k GSs of the additional level may contain all bits of the 250k GSs of the base level. For example, if a first parameter of a GS of the 250k GSs of the base level has a binary value of 0001, then a respective parameter of a respective GS of the 250k GSs of the additional level may have a binary value of 0001010100000101, which contains the binary value of the first parameter (i.e., 0001). This hierarchical structure enables a single model to support different levels of fidelity and memory usage by dynamically adjusting the number of GSs and bit depth of each configuration. The result is a flexible model that spans a grid of configurations, allowing for scalable deployment across devices with varying memory and processing constraints, without the need for separately stored models. In some embodiments, the data processing application may generate additional levels of the hierarchical data structure by increasing the bit depth of at least some parameters (e.g., position), while refraining from increasing the bit depth of other parameters (e.g., opacity).

In some embodiments, the data processing application generates and evaluates candidate additional levels. The candidate additional levels may be expected to result in substantially equal or similar memory footprints. At least one candidate additional level of the candidate additional levels may comprise more GSs than the base level. At least one candidate additional level of the candidate additional levels may comprise a number of GSs equal to a number of GSs of the base level. At least some parameters of at least one candidate additional level of the candidate additional levels may be stored at a bit depth that is greater than or equal the bit depth of at least some parameters of the base level. The data processing application may evaluate the candidate additional levels of the hierarchical data structure of GSs based at least in part on outputs of a scene fidelity loss function (e.g., respective rendered views of the 3D scene may be used as respective inputs into the scene fidelity loss function).

In some embodiments, the data processing application stores the hierarchical data structure in non-transitory memory (e.g., of one or more servers). The data processing application may cause a client device (e.g., by transmitting instructions to the client device) that is communicatively connected to the server or otherwise to the non-transitory memory to generate for display at least one rendered view of the 3D scene using at least one of the base level of the hierarchical data structure or the additional level of the hierarchical data structure.

In some embodiments, the data processing application transmits the base level of the hierarchical data structure to the client device and causes the client device to generate for display the at least one rendered view of the 3D scene using the base level of the hierarchical data structure and refraining from using the additional level of the hierarchical data structure.

In some embodiments, the data processing application transmits, to the client device, the base level of the hierarchical data structure and the additional level of the hierarchical data structure and causes the client device to generate for display the at least one rendered view of the 3D scene using the base level of the hierarchical data structure and refraining from using the additional level of the hierarchical data structure. In some embodiments, the hierarchical data structure comprises more than two levels (e.g., a first additional level, a second additional level). The data processing application may transmit, to the client device, any combination of levels of the hierarchical data structure. The data processing application may cause the client device to generate for display the at least one rendered view of the 3D scene using any combination of levels of the hierarchical data structure.

In some embodiments, the respective parameters of each GS of the subset of GSs comprises all bits of the respective parameters of each respective GS of the first plurality of GSs. This enables lower-resolution configurations to be embedding within higher ones, optimizing memory usage and eliminating redundancy.

In some embodiments, the data processing application recursively generates another additional level of the hierarchical data structure by repeating the generating the additional level of the hierarchical data structure, wherein the additional level for a current iteration is used as a new base level for a next iteration.

In some embodiments, the data processing application evaluates a plurality of candidate additional levels, wherein each of the plurality of candidate additional levels is expected to result in substantially equal or similar memory footprints. For example, a configuration comprising 250k GSs with parameters stored at 16 bits may be expected to result in substantially equal or similar memory footprint relative to a configuration comprising 500k GSs with parameters stored at 8 bits. The plurality of candidate additional levels may comprise a first candidate level that comprises a first plurality of candidate GSs. Parameters for the first plurality of candidate GSs may be stored at a first candidate bit depth, wherein the first candidate bit depth is greater than the first bit depth. The first plurality of candidate GSs may contain a number of GSs equal to the number of GSs in the first plurality of GSs. The plurality of candidate additional levels may also comprise a second candidate level that comprises a second plurality of candidate GSs.

Parameters for the second plurality of candidate GSs may be stored at a second candidate bit depth. The second candidate bit depth may be equal to the first bit depth. The second plurality of candidate GSs may comprise more GSs than the first plurality of GSs. Further, the plurality of candidate additional levels may comprise a third candidate level that comprises a third plurality of candidate GSs. Parameters for the third plurality of candidate GSs may be stored at a third candidate bit depth. The third candidate bit depth may be greater than the first bit depth. The third plurality of candidate GSs may may comprise more GSs than the first plurality of GSs. The data processing application may select one of the plurality of candidate additional levels as the additional level based on the evaluating. The data processing application may evaluate the plurality of candidate additional levels by determining a respective output of a scene fidelity loss function based on each of the plurality of candidate additional levels and comparing each respective output of the scene fidelity loss function.

In some embodiments, the second plurality of GSs contains a number of GSs equal to the number of GSs in the first plurality of GSs, and the second bit depth is greater than the first bit depth. In some embodiments, the second bit depth is equal to the first depth, and the second plurality of GSs comprises more GSs than the first plurality of GSs. In some embodiments, the second plurality of GSs comprises more GSs than the first plurality of GSs, and the second bit depth is greater than the first depth. This flexibility allows the selection of model configurations to be based on device constraints, choosing between lower bit depth or fewer GSs as needed to meet memory and processing limits.

These methods and systems may be used for 3D video and 6 degrees of freedom (6DOF) video broadcasting, in which viewers can move around within a video environment, experiencing it from different angles and positions. 3D Gaussian Splatting enables efficient rendering of these complex, dynamic scenes in real-time, making it feasible to broadcast immersive video content (e.g., live events, virtual tours, education, immersive storytelling) in which users have the freedom to explore scenes in all directions.

In some embodiments, these methods and systems are used to allow for rapid rendering of detailed environments for virtual reality (VR), augmented reality (AR), video games, film, animation, and scientific visualization (e.g., weather patterns, astronomical data) applications.

### BRIEF DESCRIPTION OF THE DRAWINGS

FIG. 1A depicts a first portion of an example schematic illustration of generating and using a hierarchical data structure of GSs, in accordance with some embodiments of this disclosure.

FIG. 1B depicts a second portion of an example schematic illustration of generating and using a hierarchical data structure of GSs, in accordance with some embodiments of this disclosure.

FIG. 2 depicts an example schematic illustration of a hierarchical model compression strategy for 3D Gaussian Splatting, in accordance with some embodiments of this disclosure.

FIG. 3 depicts an example schematic illustration of a hierarchical structure of an optimized 3D Gaussian Splatting model, a parameter structure of GSs in a 3D Gaussian Splatting model, and examples of rendering quality using different models, in accordance with some embodiments of this disclosure.

FIG. 4 depicts an example schematic illustration of a vector quantization technique, in accordance with some embodiments of this disclosure.

FIG. 5 depicts an example schematic illustration of a Gaussian pruning technique, in accordance with some embodiments of this disclosure.

FIG. 6 depicts an example sequence diagram for a hierarchical 3D Gaussian Splatting model optimization process with joint vector quantization and Gaussian pruning optimization, in accordance with some embodiments of this disclosure.

FIG. 7 depicts illustrative user equipment, in accordance with some embodiments of this disclosure.

FIG. 8 depicts an illustrative user equipment system, in accordance with some embodiments of this disclosure.

FIG. 9 depicts a flow diagram of a process for generating and using a hierarchical data structure of GSs, in accordance with some embodiments of this disclosure.

### DETAILED DESCRIPTION

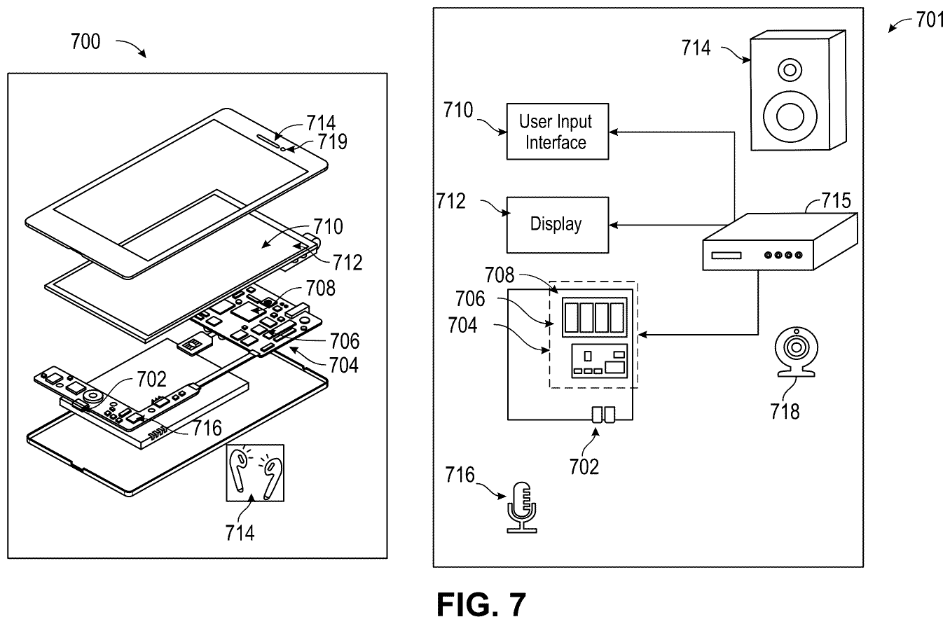

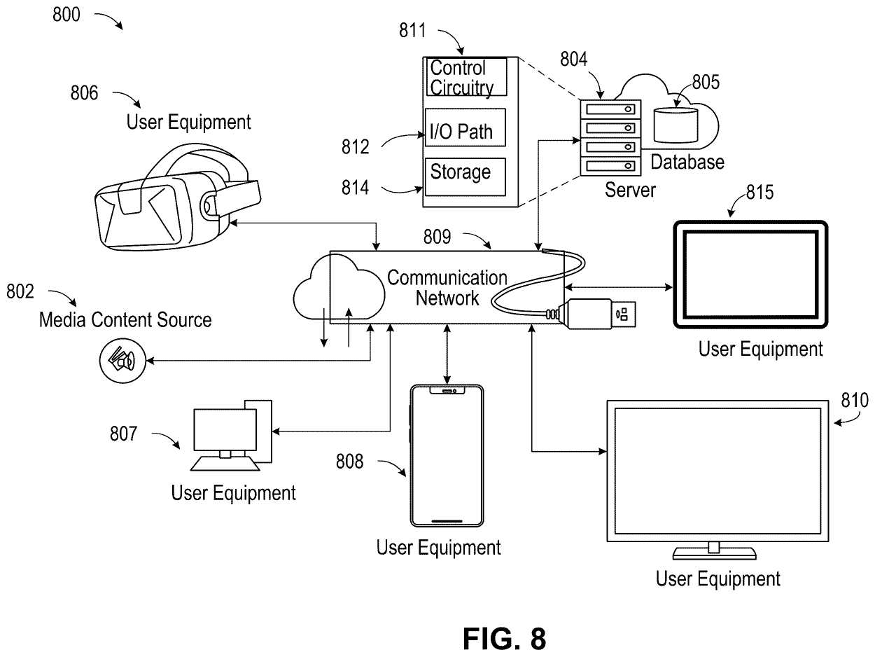

The above and other objects and advantages of the disclosure will be apparent upon consideration of the following detailed description, taken in conjunction with the accompanying drawings, in which the reference characters refer to like parts throughout. The methods and systems are described herein for incorporating hierarchical precision in a 3D Gaussian Splatting model and using the model to generate for display renders of 3D data. In some embodiments, systems described herein perform methods described herein by executing a data processing application that accesses data associated with a 3D scene and generates and stores a hierarchical data structure that is used to generate a rendered view of the 3D scene. The data processing application may be running on control circuitry (e.g., control circuitry 704 of FIG. 7, control circuitry 811 of FIG. 8), on one or more of a server, mobile services, and/or any other suitable devices or computing device, or any combination thereof. In some embodiments, the data processing application is run via a cloud computing environment, via local storage, or via any combination thereof.

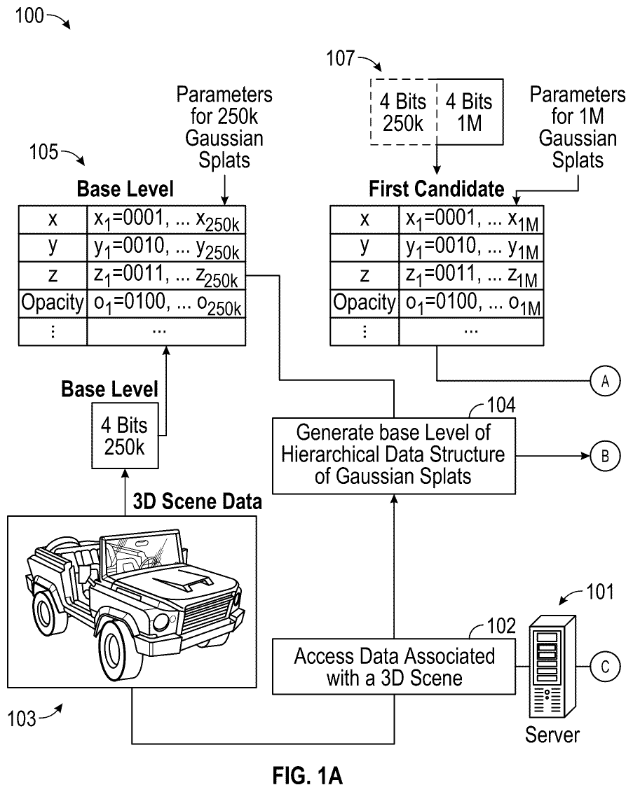

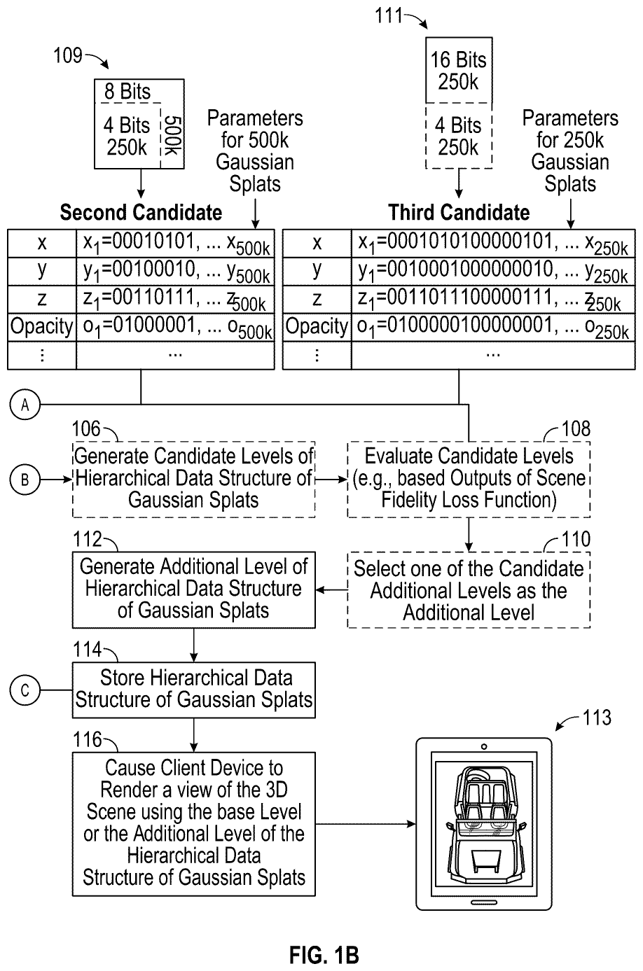

FIG. 1 and FIG. 1B depict an example schematic illustration of generating and using hierarchical data structure of GSs, in accordance with some embodiments of this disclosure.

In some embodiments, at 102, the data processing application accesses (e.g., via input/output circuitry) data associated with a 3D scene (e.g., 3D scene data 103). The data associated with the 3D scene may be 2D image data (e.g., one or more 2D images, photographs, rendered views of a 3D scene), 3D scene data (e.g., data comprising GSs, vertices, 3D object parameter, light field data), or any combination thereof.

In some embodiments, at 104, the data processing application generates (e.g., via control circuitry) a base level of the hierarchical data structure of GSs. The base level of the hierarchical data structure may be base level 105, wherein parameters (e.g., x, y, z, opacity) of a plurality (e.g., 250,000 (250k)) of GSs are stored at a bit depth of, for example, 4 bits. For example, a first GS (e.g., x₁) of the 250k GSs may comprise an x-position parameter with a 4 bit binary value of 0001. In some embodiments, position parameters of GSs may correspond to cartesian coordinates, spherical coordinates, polar coordinates, or any combination thereof. In some embodiments, parameters of the GSs may be stored at varying bit depths within a single layer of the hierarchical data structure. For example, position related parameters (e.g., x, y, z) and covariance matrix parameters may be stored at 8 bits and opacity parameters may be stored at 4 bits.

In some embodiments, the data processing application may generate the base level of the hierarchical data structure of GSs using Gaussian pruning. Gaussian pruning is a technique that may be used to optimize 3D Gaussian Splatting models by selectively reducing the number of GSs used to represent a scene. In 3D Gaussian Splatting, each GS may represent a part of the 3D scene with specific spatial, color, and opacity attributes, and the overall model fidelity improves as more GSs are used. However, using millions of GSs may lead to high memory and computational demands, which can be prohibitive for real-time applications and memory-constrained devices. Gaussian pruning may solve this issue by systematically removing less significant GSs while retaining those that contribute most to the visual quality of the scene. Gaussian pruning may involve assessing the importance of each GS based on factors such as opacity, spatial redundancy, visual impact, or any combination thereof. Low-opacity GSs that contribute minimally to the rendered scene or GSs that represent redundant or less visually critical areas may be identified as candidates for removal via Gaussian pruning. This process enables a reduction in the total number of GSs, creating lower-density models that are more compact and suitable for lower-end devices.

In some embodiments, at 106, the data processing application generates candidate levels (e.g., first candidate level 107, second candidate level 109, third candidate level 111) of the hierarchical data structure of GSs. The candidate levels may be expected to result in substantially equal or similar memory footprints. For example, a first candidate level may comprise twice as many GSs that have parameters stored at half the bit depth relative to a second candidate level. For cases in which parameters of GSs of candidate levels are stored at a bit depth that is greater than the bit depth that parameters of GSs of the base layer are stored at (e.g., candidate levels 109 and 111), the parameters of GSs of the candidate levels may comprise all bits of the respective parameters of the GSs of the base layer. For example, the x₁ parameter of second candidate level 109 has an 8 bit binary value of 00010101, which comprises all bits of the respective x₁ parameter of the GSs of the base layer, which has a 4 bit binary value of 0001. As another example, the x₁ parameter of third candidate level 111 has a 16 bit binary value of 0001010100000101, which comprises all bits of the respective x₁ parameter of the GSs of the base layer, which has a 4 bit binary value of 0001.

In some embodiments, at 108, the data processing application evaluates the candidate levels 107, 109, 111 of the hierarchical data structure of GSs. The evaluation may be based at least in part on outputs of a scene fidelity loss function. For example, first candidate level 107, second candidate level 109, and third candidate level 111 may be used to render respective views of the 3D scene. The respective rendered views of the 3D scene may be used as respective inputs into the scene fidelity loss function. Comparison of the respective outputs of the scene fidelity loss function corresponding to the first candidate level 107, second candidate level 109, and third candidate level 111 may be used to select the additional level of the hierarchical data structure of GSs at step 110. For example, the candidate level corresponding to the minimum respective output of the scene fidelity loss function may be selected as the additional level of the hierarchical data structure of GSs.

In some embodiments, at 110, the data processing application selects one of the candidate additional levels as the additional level of the hierarchical data structure of GSs (e.g., based on the evaluation of the candidate levels). The selection of an additional level of the hierarchical data structure of GSs may be performed without the generation and evaluation of candidate levels, rendering steps 106 and 108 as optional. The selection of the additional level may be performed based on a user input via a client device, an output of a computational model (e.g., a machine learning (ML) model), previous selections of additional levels, or any combination thereof.

In some embodiments, at 112, the data processing application generates the additional level of the hierarchical data structure of GSs. The generation of the additional level of the hierarchical data structure may be based on the selection of step 110. In some embodiments, the generation of the additional level of the hierarchical data structure is performed without generating, evaluating, and selecting candidate additional levels, rendering steps 106, 108, and 110 as optional. In some embodiments, the data processing application repeats step 112 recursively, wherein, at each iteration, the data processing application uses the additional level from a current iteration as a new base level for a next iteration. For example, base level 105 may have been the additional level of a previous iteration of the recursion. As another example, the data processing application may select the second candidate level 109 as the additional level of the hierarchical data structure during a current iteration of the recursion, and, in a next iteration of the recursion, the data processing application may use the second candidate level 109 as a new base level.

In some embodiments, at 114, the data processing application stores the hierarchical data structure of GSs. For example, the data processing application may store the hierarchical data structure of GSs in non-transitory memory (e.g., storage 708 of FIG. 7) of a server (e.g., server 101, server 804 of FIG. 8). In some embodiments, a clustering algorithm may be used to reduce the storage requirements of 3D Gaussian Splatting models by representing parameters of with fewer bits.

In some embodiments, at 116, the data processing application causes a client device (e.g., user equipment 700 of FIG. 7, 701 of FIG. 7, 806 of FIG. 8, 807 of FIG. 8, 808 of FIG. 8, 810 of FIG. 8, 815 of FIG. 8) that is communicatively connected (e.g., via communication network 809) to server 101 to render a view of the 3D scene (e.g., rendered view 113) using the base level and/or the additional level of the hierarchical data structure of GSs. In some embodiments, the additional level of the hierarchical data structure comprises the information contained in the base level of the hierarchical data structure, allowing the additional level of the hierarchical data structure of GSs to be used for rendering without use of the base level. In some embodiments, GSs of the additional level of the hierarchical data structure comprise respective links and/or pointers (e.g., as metadata) to GSs of the base level of the hierarchical data structure, allowing the additional level of the hierarchical data structure to be used for rendering in combination with the base level. The data processing application may determine which level or levels of the hierarchical data structure to use for generating for display the rendered view of the 3D scene based on client device capabilities. For example, if the client device is a low capacity device (e.g., a mobile phone), then the data processing application may determine to send the base level of the hierarchical data structure to the client device for rendering the 3D scene. If the client device is a high capacity device (e.g., a supercomputer), then the data processing application may determine to send a higher fidelity configuration (e.g., the additional level) to the client device for rendering the 3D scene. The data processing application may cause the client device to generate for display the rendered view of the 3D scene (e.g., rendered view 113). The 3D scene may be rendered by setting a virtual camera (e.g., by choosing position and orientation parameters for the virtual camera) in the space of the 3D scene and rendering GSs that are in the field of view of the virtual camera. In some embodiments, system 100 includes multiple servers, multiple client devices, and/or is part of a cloud computing environment.

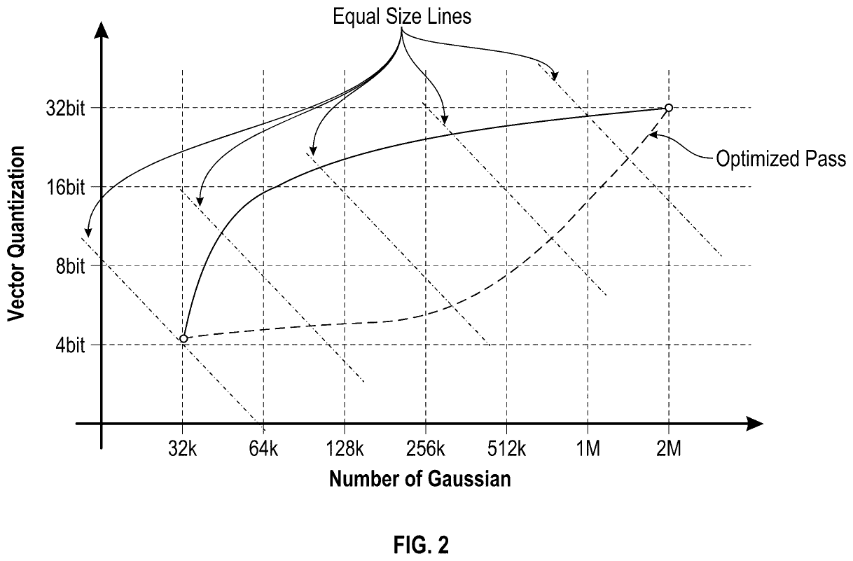

FIG. 2 depicts an example schematic illustration of a hierarchical model compression strategy for 3D Gaussian Splatting, in accordance with some embodiments of this disclosure. In some embodiments, hierarchical model compression strategy for 3D Gaussian Splatting integrates vector quantization and Gaussian pruning within a single hierarchical model. The x-axis of FIG. 2 shows the number of GSs, also referred to herein as Gaussian count, used to represent the scene, increasing from left to right. The y-axis of FIG. 2 shows the bit depth used in vector quantization, increasing from 4-bit to 32-bit from bottom to top. The diagonal lines represent equal size lines, wherein each configuration along an equal size line may be expected to result in substantially equal or similar memory footprints while offering different balances between bit depth and Gaussian count. For example, a first configuration may comprise twice as many GSs that have parameters stored at half the bit depth relative to a second configuration level along an equal size line. Each configuration of FIG. 2 may correspond to a base level (e.g., base level 105 of FIG. 1A) of the hierarchical data structure, a candidate additional level (e.g., first candidate additional level 107 of FIG. 1A, second candidate additional level 109 of FIG. 1B, third candidate additional level 111 of FIG. 1B), or an additional level of the hierarchical data structure.

The optimized pass illustrates an example training process in which the model begins with a relatively small configuration (e.g., 32K Gaussians at 4 bits) and iteratively augments with additional GSs and/or greater bit depths. This structure allows the model to contain multiple fidelity levels, adapting in real time to various device constraints without requiring separate models. This approach efficiently embeds different model configurations, enabling flexibility and optimized quality-size trade-offs across a spectrum of deployment scenarios. An advantage of this solution over existing methods lies in its efficiency and adaptability. Traditional approaches may require creating and storing separate models for each configuration, resulting in significant storage redundancy and inefficient memory use. The methods and system disclosed herein, however, provide a streamlined structure that combines multiple configurations in a compact format, reducing storage requirements and enabling seamless transitions between model resolutions. Furthermore, by allowing for on-demand adjustments of bit depth and Gaussian count, this solution enhances the real-time adaptability of 3D Gaussian Splatting, which is especially beneficial in resource-constrained environments such as mobile and AR/VR devices. For example, this could be used for adaptive delivery and presentation of 3D volumetric assets.

In some embodiments, parameters for a single GS of a single configuration are stored at different bit depths from each other. For example, position parameters for GSs may be stored at a higher bit depth than opacity parameters. In some embodiments, parameters for a first GS of a first configuration are stored at different bit depths from a second GS of the first configuration. The vector quantization levels of FIG. 2 (e.g., 4 bit, 8 bit, 16 bit, 32 bit, etc.) may correspond to a bit depth statistic (e.g., mean, median, mode, minimum, maximum) of parameters of GSs, wherein the bit depth statistic may be calculated over a plurality of parameters and/or a plurality of GSs of a configuration.

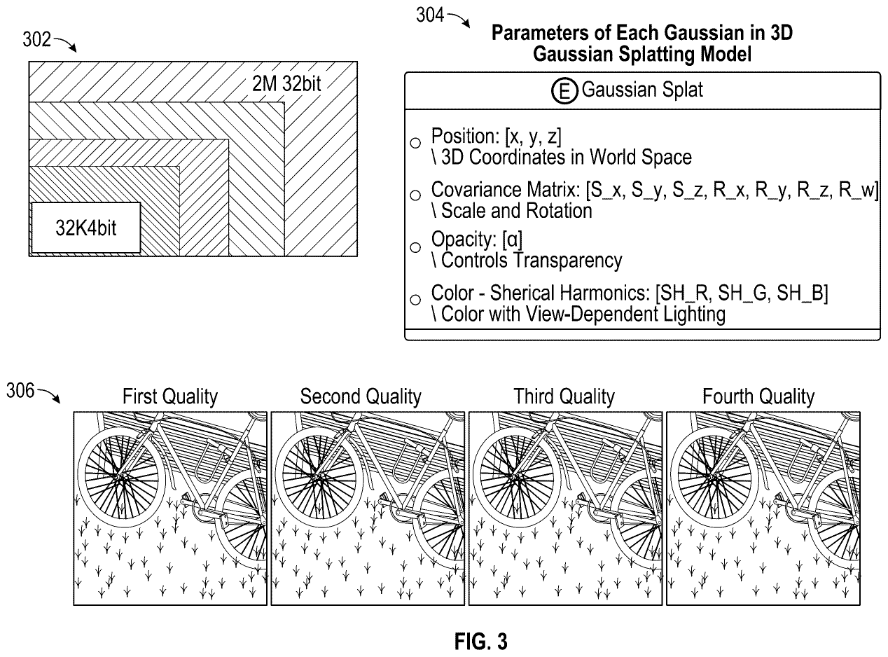

FIG. 3 depicts an example schematic illustration of a hierarchical structure of an optimized 3D Gaussian Splatting model in which smaller, lower-fidelity configurations are embedded within progressively finer, higher-fidelity configurations. FIG. 3 also depicts a parameter structure of GSs in a 3D Gaussian Splatting model, and examples of rendering quality using different models, in accordance with some embodiments of this disclosure.

Block 302 represents a multi-level 3D Gaussian Splatting model structured to contain a range of configurations, from a compact configuration of 32K GSs at 4-bit quantization to a high-fidelity configuration of 2M GSs at 32-bit quantization. Each inner layer represents a smaller configuration that is embedded within a larger one, enabling a seamless transition between levels of model fidelity. This hierarchy allows the model to adapt to different memory and processing constraints dynamically, using lower levels for resource-constrained devices and higher levels for powerful systems. This structure provides an efficient and flexible approach to 3D scene rendering, with optimized quality-size trade-offs and minimal redundancy. As shown in block 304, each GSs in the 3D Gaussian Splatting model may comprise four categories of parameters: position, covariance matrix, opacity, and color. Position represents the 3D coordinates (e.g., cartesian coordinates x, y, z), specifying where the GS is located within the scene, and can be quantized to different bit depths based on fidelity requirements. The covariance matrix defines the GS's size, orientation, and shape, with scaling factors (e.g., S_x, S_y, S_z) for size along each axis, and a quaternion (e.g., R_x, R_y, R_z, R_w) to control the GS's orientation in 3D space. Opacity, which may be represented by a, may control transparency on a scale from 0 (transparent) to 1 (opaque), influencing how the GS visually blends with other GSs in the scene. Color, which may be defined by spherical harmonics (SH) coefficients for the red, green, and blue channels (e.g., SH_R, SH_G, SH_B), enables view-dependent color variations, simulating realistic lighting effects. Each parameter may be quantized such that lower fidelity levels use fewer bits for compression, while higher fidelity levels increase bit depth to capture more detail and visual accuracy. For example, candidate levels 109 and 111 of FIG. 1B comprise parameters that are stored at a higher bit depth relative to the base level 105 of FIG. 1A. Scenes 306 depict some examples of rendering quality (e.g., first quality, second quality, third quality, fourth quality) using different configurations of a 3D Gaussian Splatting model, from higher quality (left) to lower quality (right). For example, the first quality render may rendered using a higher bit-depth and/or a larger number of GSs relative to the second quality render. The second quality render may rendered using a higher bit-depth and/or a larger number of GSs relative to the third quality render. The third quality render may rendered using a higher bit-depth and/or a larger number of GSs relative to the fourth quality render.

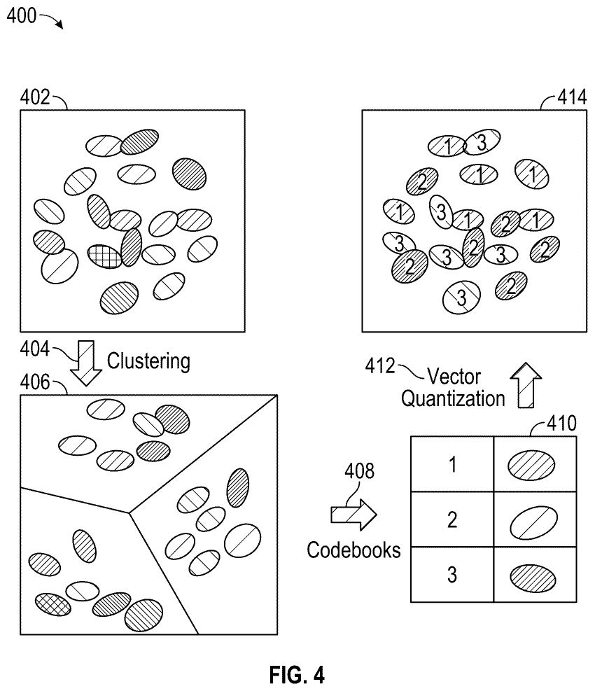

FIG. 4 depicts an example schematic illustration of a vector quantization technique 400, in accordance with some embodiments of this disclosure. Vector quantization is a compression technique used to reduce the storage requirements of 3D Gaussian Splatting models by representing parameters with fewer bits. Each GS in a scene has multiple categories of parameters, such as position, color, and opacity, which traditionally require a large amount of storage if represented in full precision (e.g., 32-bit floating points). Vector quantization may address this challenge by encoding these categories of parameters into clusters, wherein similar data points may be grouped and represented by a shared approximation, effectively reducing the number of bits needed to store each attribute. For example, GSs with opacity values between 0.1 and 0.2 on a scale of 0 to 1 may be clustered together and represented by a single value. The single value may be any value bounded by the parameter values of GSs belonging to the cluster. For example, GSs with opacity values between 0.1 and 0.2 on a scale of 0 to 1 may be represented by a value of 0.15 (i.e., the center of the cluster boundaries) or a statistical value (e.g., mean, median, mode) of parameter values of GSs belonging to the cluster.

At 404, the data processing application may identify, based on GSs 402, clusters within a data space of GS parameters 406 (e.g., using K-means clustering). At 408, the data processing application may create a codebook of representative vectors 410 for each cluster (e.g., clusters 1, 2, and 3 of 410). At 412, the data processing application may apply the vector quantization clustering to the GSs of 402, resulting in the GSs of 414, which require less memory to store than the GSs of 402. For example, if the three values of 410 correspond to three different opacity values, then the memory required to store the 18 different opacity values of the GSs of 402 (i.e., one opacity value for each GS) is 6 times greater than memory required to store the three different clustered opacity values of the GSs of 414. In some embodiments, the y-axis of FIG. 2 may represent an effective bit depth, wherein the effective bit depth is based at least in part on the clustered GS parameters (e.g., parameters of the GSs of 414). GSs within a same layer of the hierarchical data structure and/or GSs belonging to different levels of the hierarchical data structure may be clustered using the same codebook or different codebooks.

3D Gaussian Splatting models may be quantized at various bit depths (e.g., 4-bit, 8-bit, 16-bit), with each bit depth offering a different trade-off between compression and fidelity. For example, a 4-bit quantized model (e.g., base level 105 of FIG. 1A, first candidate level 107 of FIG. 1B) uses only the most significant 4 bits of each parameter, resulting in a highly compressed but lower-fidelity representation. Configurations with higher bit depths (e.g., second candidate level 109 of FIG. 1B, third candidate level 111 of FIG. 1B) retain more detail by using more bits, allowing for progressively finer control over rendering quality.

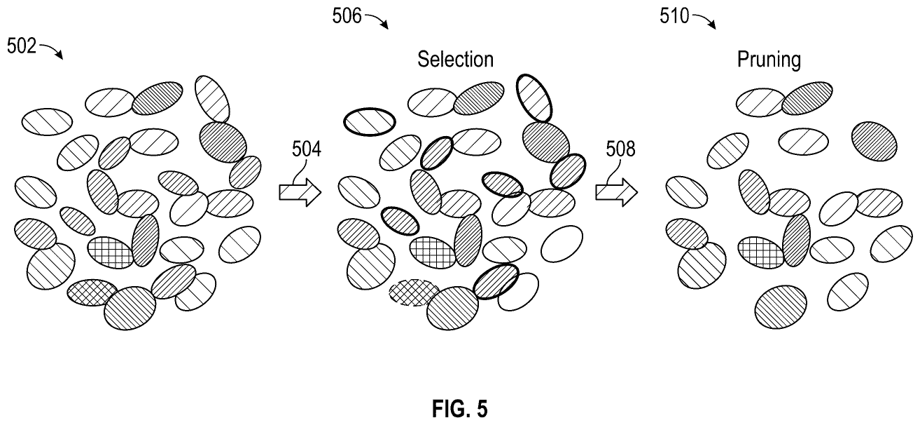

FIG. 5 depicts an example schematic illustration of a Gaussian pruning technique, in accordance with some embodiments of this disclosure. Gaussian pruning is a technique that may be used to optimize 3D Gaussian Splatting models by selectively reducing the number of GSs used to represent a scene. In 3D Gaussian Splatting, each GS may represent a part of the 3D scene with specific spatial, color, and opacity attributes, and the overall model fidelity improves as more GSs are used. However, using a large number of GSs may lead to high memory and computational demands, which can be prohibitive for real-time applications and memory-constrained devices. Gaussian pruning may solve this issue by systematically removing less significant GSs while retaining those that contribute most to the visual quality of the scene. Gaussian pruning may involve assessing the importance of each GS based on factors such as opacity, spatial redundancy, visual impact, or any combination thereof. Low-opacity GSs that contribute minimally to the rendered scene or GSs that represent redundant or less visually critical areas may be identified as candidates for removal via Gaussian pruning. This process enables a reduction in the total number of GSs, creating lower-density models that are more compact and suitable for lower-end devices, for instance.

In some embodiments, at 504, GSs from a first plurality of GSs 502 are selected for pruning, as indicated in 506 by the bold outlines. At 508, the selected GSs are pruned from the first plurality of GS 502, resulting in a second plurality of GSs 510. For example, the base level 105 of FIG. 1A may have resulted from a Gaussian pruning procedure. In this example, the base level 105 of FIG. 1A would correspond to the second plurality of GSs 510.

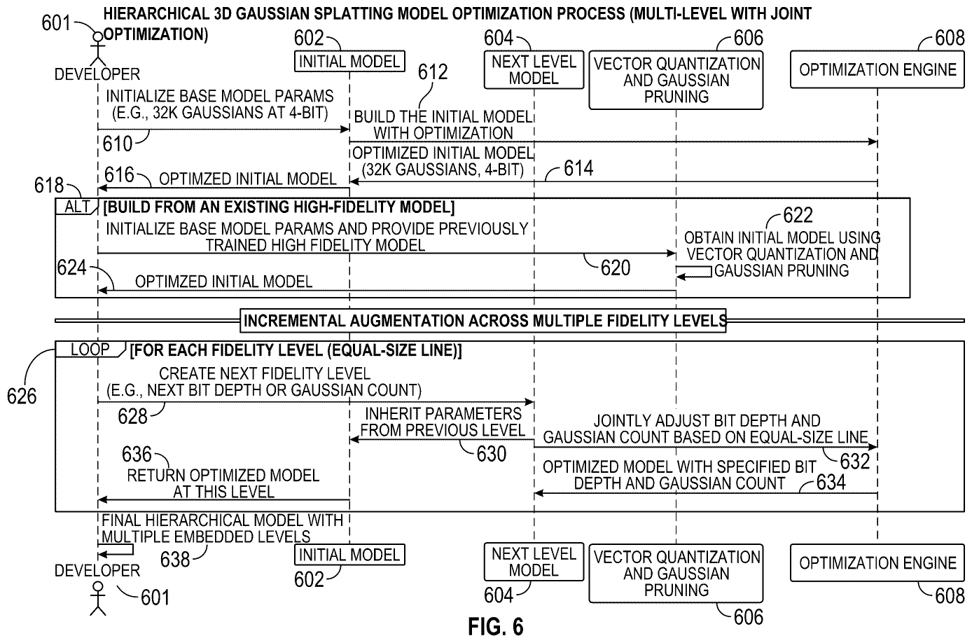

FIG. 6 depicts an example sequence diagram for a hierarchical 3D Gaussian Splatting model optimization process with joint vector quantization and Gaussian pruning optimization, in accordance with some embodiments of this disclosure.

In some embodiments, at 610, the data processing application (e.g., the data processing application of FIG. 1A and FIG. 1B, or a different data processing application from FIG. 1A and FIG. 1B) initializes (e.g., in response to a request from developer 601) base model parameters (e.g., 32K GSs at a bit depth of 4 bits) of an initial model 602. For example, the initial model 602 may comprise base level parameters 105 of FIG. 1A.

In some embodiments, at 612, the data processing application builds the initial model with optimization (e.g., using optimization engine 608). The optimization objective may be to maximize a scene fidelity (e.g., by minimizing a scene fidelity loss function) at a fixed Gaussian count and bit depth. The scene fidelity loss function may be formalized, for example, by the following equation:

$${min}_{θ} {\sum }_{i = 0}^{N} {‖ {I}_{rend ered ( θ , G )} - {I}_{target} ‖}^{2}$$

wherein, I_{rendered}(θ, G) represents the i^{th} pixel of the rendered image based on GS parameters θ (e.g., position, opacity, color), wherein I_{target} represents the i^{th} pixel of the target image from a training dataset, wherein G represents 3D Gaussian Splatting hyperparameters (e.g., bit depth, Gaussian count), and wherein i represents an index for pixels in the rendered target images. For example, if the rendered and target images are 100×100 pixel images, then i may correspond to the indices of the flatted images, ranging from 0 to 9999 (i.e., N=9999). The optimization may find the parameters θ that minimize a distance metric between the rendered and target images (e.g., L1 norm, L2 norm, squared error, mean squared error, absolute error). The scene fidelity loss function may be formalized in accordance with any distance metric between the rendered and target images. At 614, the data processing application may incorporate the optimized initial model (e.g., base level 105 of FIG. 1A) into the initial model 602. At 616, the data processing application may send the optimized initial model back to developer 601.

In some embodiments, 618 represents an alternative approach to initializing a base model. The data processing application may, at 620, initialize base model parameters and provide a previously trained model (e.g., a high fidelity model). At 622, the data processing application may obtain the initial model using vector quantization and/or Gaussian pruning. At 624, the data processing application may send the optimized initial model back to developer 601.

In some embodiments, 626 represents an approach for incremental augmentation across multiple fidelity levels. At 628, the data processing application may create a next fidelity level for the next level model 604. At 630, the data processing application may inherit parameters from the previous level of the model. At 632, the data processing application may jointly adjust bit depth and Gaussian count. For example, the data processing application may search configurations on the next equal size line of FIG. 2 (e.g., by increasing bit depth and/or Gaussian count). At 634, the data processing application may optimize the model with the specified bit depth and Gaussian count. At 636, the data processing application may return the optimized model to developer 601.

In some embodiments, each configuration of the hierarchical data structure at a given Gaussian count and bit depth contains all configurations with lower Gaussian counts and lower bit depths. This allows for seamless scalability within a single model. At each level of bit depth, the data processing application may retain the significant bits of all previous levels. In some embodiments, the vector quantization for 3D Gaussian Splatting contains an index map, wherein a parameter of a GS is quantized such that the parameter will represent a specific value, p (e.g., 0.6). For each vector quantization level of the hierarchical model, the model may also record the relationship between values of the parameter, p, and decimal representation, p_{q}. For example, for an 8-bit model, p_{q} may take binary values represented by integers between 0 and 255, while p may correspond to mapped values (e.g., between −1 and 1), wherein the mapped values are clustered into 256 levels. In some embodiments, for a bit depth of n, each parameter p may be mapped to decimal representation, p_{q}, according to the following equation:

$${p}_{q} = \frac{( p - {p}_{min} ) \times ( {2}^{n} - 1 )}{{p}_{max} - {p}_{min}}$$

wherein pₘᵢₙ and pₘₐₓ represent the minimum and maximum possible values of p, respectively. This equation maps the parameter p linearly into an integer range [0, 2ⁿ−1] based on the defined range. This transformation ensures that the quantized values span the full range of possible values for the parameter, making efficient use of the available bits while preserving fidelity.

In some embodiments, different GSs parameters may have different quantization parameters (e.g., pₘᵢₙ, pₘₐₓ). For example, some parameters may have their own index maps, some may have their own pₘᵢₙ and pₘₐₓ. Those parameters can be grouped together into attributes such as positions, covariance matrix, opacity, and color, which may be represented by spherical harmonics coefficients. In some embodiments, groups share quantization parameters, while in some groups, different attributes may have different quantization parameters.

In the hierarchical data structure, each bit-depth level may contain all quantized values from previous levels. For example, an 8-bit quantized model may include the 4-bit quantized model by using only the most significant 4 bits, with the remaining bits provide additional detail. The quantized representation at 8 bits, p_{q,8}, may be formalized by the following equation:

$${p}_{q , 8} = {p}_{q , 4} \times 16 + Δ$$

wherein Δ represents the additional information contained in the bits beyond 4-bit precision.

When increasing bit depth, the quantized values from the previous level may serve as a base, with additional bits added to refine precision. The optimization may only focus on refining the added bits rather than re-optimizing all parameters. For example, moving from a 4-bit to an 8-bit model involves only adding A to the original 4-bit parameters, wherein Δ is the additional information contained in the next 4 bits, while keeping the original 4 bits the same. In some embodiments, the quantization parameters (e.g., indexing map, pₘᵢₙ, pₘₐₓ) may be changed for each of the configuration.

When increasing the Gaussian count, additional GSs may be initialized based on scene structure (e.g., using importance sampling to determine where additional splats are needed). New GSs may be placed in regions where they will most improve scene fidelity without altering the parameters of the existing GSs. In some embodiments, the increasing in bit depth and Gaussian count may be done in sequence, with one optimized first before optimizing the other one. In some embodiments, increasing of bit depth and Gaussian count may be done in parallel through a joint optimization.

In some embodiments, at 638, the data processing application may return the final hierarchical model with multiple embedded levels to developer 601 (e.g., via client device 113 of FIG. 1B).

FIG. 7 depicts an illustrative user equipment 700 and 701, in accordance with some embodiments of this disclosure. For example, user equipment 700 may be a smartphone device or tablet equipped with audio output equipment 714, visual display 712, user input interface 710, memory storage 708, processing circuitry 706, control circuitry 704, input/output (I/O) path 702, camera 719, and microphone 716. In some embodiments, user equipment 701 may be a user television equipment system or device. User equipment 701 may include set-top box 715. Set-top box 715 may be communicatively connected to microphone 716, audio output equipment 714 (e.g., speaker or headphones), and display 712. In some embodiments, microphone 716 may receive audio corresponding to a voice of a user and/or ambient audio data. In some embodiments, display 712 may be a television display or a computer display. In some embodiments, set-top box 715 may be communicatively connected to user input interface 710. In some embodiments, user input interface 710 may be a remote-control device. Set-top box 715 may include one or more circuit boards. In some embodiments, the circuit boards may include control circuitry 704, processing circuitry 706, and storage 708 (e.g., RAM, ROM, hard disk, removable disk, etc.). In some embodiments, the circuit boards may include an input/output path 702.

Each one of user equipment 700 and user equipment 701 may receive content and data via input/output (I/O) path 702. I/O path 702 may provide supplemental content (e.g., audio or visual media) and data to control circuitry 704, which may comprise processing circuitry 706 and storage 708. Control circuitry 704 may be used to send and receive commands, requests, and other suitable data using I/O path 702, which may comprise I/O circuitry. While set-top box 715 is shown in FIG. 7 for illustration, any suitable computing device having processing circuitry, control circuitry, and storage may be used in accordance with the present disclosure. For example, set-top box 715 may be replaced by, or complemented by, a personal computer (e.g., a notebook, a laptop, a desktop), a smartphone (e.g., user equipment 700), an XR device, a tablet, a network-based server hosting a user-accessible client device, a non-user-owned device, any other suitable device, or any combination thereof.

Control circuitry 704 may be based on any suitable control circuitry such as processing circuitry 706. As referred to herein, control circuitry should be understood to mean circuitry based on one or more microprocessors, microcontrollers, digital signal processors, programmable logic devices, field-programmable gate arrays (FPGAs), application-specific integrated circuits (ASICs), etc., and may include a multi-core processor (e.g., dual-core, quad-core, hexa-core, or any suitable number of cores) or supercomputer. In some embodiments, control circuitry may be distributed across multiple separate processors or processing units, for example, multiple of the same type of processing units (e.g., two Intel Core i7 processors) or multiple different processors (e.g., an Intel Core i6 processor and an Intel Core i7 processor). In some embodiments, control circuitry 704 executes instructions for the system stored in memory (e.g., storage 708). Specifically, control circuitry 704 may be instructed by the system to perform the functions discussed above and below. In some implementations, processing or actions performed by control circuitry 704 may be based on instructions received from the system.

In client/server-based embodiments, control circuitry 704 may include communications circuitry suitable for communicating with a server or other networks or servers. The system may be a stand-alone application implemented on a device or a server. The application (e.g., the data processing application of FIG. 1A and FIG. 1B) may be implemented as software or a set of executable instructions. The instructions for performing any of the embodiments discussed herein of the application may be encoded on non-transitory computer-readable media (e.g., a hard drive, random-access memory on a DRAM integrated circuit, read-only memory on a BLU-RAY disk, etc.). For example, in FIG. 7, the instructions may be stored in storage 708, and executed by control circuitry 704 of a user equipment 700.

In some embodiments, the application may be a client/server application where only the client application resides on user equipment 700, and a server application resides on an external server (e.g., server 804 and/or media content source 802). For example, the application may be implemented partially as a client application on control circuitry 704 of user equipment 700 and partially on server 804 as a server application running on control circuitry 811. Server 804 may be a part of a local area network with one or more of user equipment 700, 701 or may be part of a cloud computing environment accessed via the internet. In a cloud computing environment, various types of computing services for performing searches on the internet or informational databases, providing video communication capabilities, providing storage (e.g., for a database) or parsing data are provided by a collection of network-accessible computing and storage resources (e.g., server 804 and/or an edge computing device), referred to as “the cloud.” User equipment 700 may be a cloud client that relies on the cloud computing capabilities from server 804 to generate personalized supplemental content.

Control circuitry 704 may include communications circuitry suitable for communicating with a server, edge computing systems and devices, a table or database server, or other networks or servers. The instructions for carrying out the above-mentioned functionality may be stored on a server (which is described in more detail in connection with FIG. 8). Communications circuitry may include a cable modem, an integrated services digital network (ISDN) modem, a digital subscriber line (DSL) modem, a telephone modem, an Ethernet card, or a wireless modem for communications with other equipment, or any other suitable communications circuitry. Such communications may involve the internet or any other suitable communication networks or paths (which is described in more detail in connection with FIG. 8).

In addition, communications circuitry may include circuitry that enables peer-to-peer communication of user equipment, or communication of user equipment in locations remote from each other (described in more detail below).

Memory may be an electronic storage device provided as storage 708 that is part of control circuitry. As referred to herein, the phrase “electronic storage device” or “storage device” should be understood to mean any device for storing electronic data, computer software, or firmware, such as random-access memory, read-only memory, hard drives, optical drives, digital video disc (DVD) recorders, compact disc (CD) recorders, BLU-RAY disc (BD) recorders, BLU-RAY 3D disc recorders, digital video recorders (DVRs, sometimes called personal video recorders, or PVRs), solid state devices, quantum storage devices, gaming consoles, gaming media, or any other suitable fixed or removable storage devices, and/or any combination of the same. Storage 708 may be used to store various types of content described herein as well as application data described above. Nonvolatile memory may also be used (e.g., to launch a boot-up routine and other instructions). Cloud-based storage, described in relation to FIG. 7, may be used to supplement storage 708 or instead of storage 708. Non-transitory memory may store instructions that, when executed by control circuitry, I/O circuitry, any other suitable circuitry or combination thereof, executes functions of an application as described above.

Control circuitry 704 may include video generating circuitry and tuning circuitry, such as one or more analog tuners, one or more MPEG-2 decoders or HEVC decoders or any other suitable digital decoding circuitry, high-definition tuners, or any other suitable tuning or video circuits or combinations of such circuits. Encoding circuitry (e.g., for converting over-the-air, analog, or digital signals to MPEG or HEVC or any other suitable signals for storage) may also be provided. Control circuitry 704 may also include scaler circuitry for upconverting and downconverting content into the preferred output format of user equipment 700. Control circuitry 704 may also include digital-to-analog converter circuitry and analog-to-digital converter circuitry for converting between digital and analog signals. The tuning and encoding circuitry may be used by user equipment 700 and 701 to receive and to display, to play, or to record content. The tuning and encoding circuitry may also be used to receive video communication session data. The circuitry described herein, including, for example, the tuning, video generating, encoding, decoding, encrypting, decrypting, scaler, and analog/digital circuitry, may be implemented using software running on one or more general purpose or specialized processors. Multiple tuners may be provided to handle simultaneous tuning functions (e.g., watch and record functions, picture-in-picture (PIP) functions, multiple-tuner recording, etc.). If storage 708 is provided as a separate device from user equipment 700, the tuning and encoding circuitry (including multiple tuners) may be associated with storage 708.

Control circuitry 704 may receive instruction from a user by way of user input interface 710. User input interface 710 may be any suitable user interface, such as a remote control, mouse, trackball, keypad, keyboard, touch screen, touchpad, stylus input, joystick, voice recognition interface, or other user input interfaces. Display 712 may be provided as a stand-alone device or integrated with other elements of each one of user equipment 700 and user equipment 701. For example, display 712 may be a touchscreen or touch-sensitive display. In such circumstances, user input interface 710 may be integrated with or combined with display 712. In some embodiments, user input interface 710 includes a remote-control device having one or more microphones, buttons, keypads, any other components configured to receive user input or combinations thereof. For example, user input interface 710 may include a handheld remote-control device having an alphanumeric keypad and option buttons. In a further example, user input interface 710 may include a handheld remote-control device having a microphone and control circuitry configured to receive and identify voice commands and transmit information to set-top box 715.

Audio output equipment 714 may be integrated with or combined with display 712. Display 712 may be one or more of a monitor, television, liquid crystal display (LCD) for a mobile device, amorphous silicon display, low-temperature polysilicon display, electronic ink display, electrophoretic display, active matrix display, electro-wetting display, electro-fluidic display, cathode ray tube display, light-emitting diode display, electroluminescent display, plasma display panel, high-performance addressing display, thin-film transistor display, organic light-emitting diode display, surface-conduction electron-emitter display (SED), laser television, carbon nanotubes, quantum dot display, interferometric modulator display, or any other suitable equipment for displaying visual images. A video card or graphics card may generate the output to the display 712. Audio output equipment 714 may be provided as integrated with other elements of each one of user equipment 700 and user equipment 701 or may be stand-alone units. An audio component of videos and other content displayed on display 712 may be played through speakers (or headphones) of audio output equipment 714. In some embodiments, audio may be distributed to a receiver (not shown), which processes and outputs the audio via speakers of audio output equipment 714. In some embodiments, for example, control circuitry 704 is configured to provide audio cues to a user, or other audio feedback to a user, using speakers of audio output equipment 714. There may be a separate microphone 716 or audio output equipment 714 may include a microphone configured to receive audio input such as voice commands or speech. For example, a user may speak letters or words that are received by the microphone and converted to text by control circuitry 704. In a further example, a user may voice commands that are received by a microphone and recognized by control circuitry 704. Camera 718 (e.g., surveillance camera 134 of FIGS. 1A and 1B) may be any suitable video camera integrated with the equipment or externally connected. Camera 718 may be a digital camera comprising a charge-coupled device (CCD) and/or a complementary metal-oxide semiconductor (CMOS) image sensor. Camera 718 may be an analog camera that converts to digital images via a video card.

The application may be implemented using any suitable architecture. For example, it may be a stand-alone application wholly implemented on each one of user equipment 700 and user equipment 701. In such an approach, instructions of the application may be stored locally (e.g., in storage 708), and data for use by the application is downloaded on a periodic basis (e.g., from an out-of-band feed, from an internet resource, or using another suitable approach). Control circuitry 704 may retrieve instructions of the application from storage 708 and process the instructions to provide video conferencing functionality and generate any of the displays discussed herein. Based on the processed instructions, control circuitry 704 may determine what action to perform when input is received from user input interface 710. For example, movement of a cursor on a display up/down may be indicated by the processed instructions when user input interface 710 indicates that an up/down button was selected. An application and/or any instructions for performing any of the embodiments discussed herein may be encoded on computer-readable media. Computer-readable media includes any media capable of storing data. The computer-readable media may be non-transitory including, but not limited to, volatile and non-volatile computer memory or storage devices such as a hard disk, floppy disk, USB drive, DVD, CD, media card, register memory, processor cache, random access memory (RAM), etc.

Control circuitry 704 may allow a user to provide user profile information or may automatically compile user profile information. For example, control circuitry 704 may access and monitor network data, video data, audio data, processing data, content consumption data, and/or any other suitable data being accessed by a first user (e.g., user 140 of museum device 120). Control circuitry 704 may obtain all or part of other user profiles that are related to a particular user (e.g., via social media networks), and/or obtain information about the user from other sources that control circuitry 704 may access. As a result, a user may be provided with a unified experience across the user's different devices.

In some embodiments, the application (e.g., the data processing application) is a client/server-based application (e.g., running via server 132 of FIGS. 1A and 1B). Data for use by a thick or thin client implemented on each one of user equipment 700 and user equipment 701 may be retrieved on demand by issuing requests to a server remote to each one of user equipment 700 and user equipment 701. For example, the remote server may store the instructions for the application in a storage device. The remote server may process the stored instructions using circuitry (e.g., control circuitry 704) and generate the displays discussed above and below. The user equipment may receive the displays generated by the remote server and may display the content of the displays locally on user equipment 700. This way, the processing of the instructions is performed remotely by the server while the resulting displays (e.g., that may include text, a keyboard, or other visuals) are provided locally on user equipment 700. User equipment 700 may receive inputs from the user via user input interface 710 and transmit those inputs to the remote server for processing and generating the corresponding displays. For example, user equipment 700 may transmit a communication to the remote server indicating that an up/down button was selected via user input interface 710. The remote server may process instructions in accordance with that input and generate a display of the application corresponding to the input (e.g., a display that moves a cursor up/down). The generated display is then transmitted to user equipment 700 for presentation to the user.

In some embodiments, the application may be downloaded and interpreted or otherwise run by an interpreter or virtual machine (run by control circuitry 704). In some embodiments, the application may be encoded in the ETV Binary Interchange Format (EBIF), received by control circuitry 704 as part of a suitable feed, and interpreted by a user agent running on control circuitry 704. For example, the application may be an EBIF application. In some embodiments, the application may be defined by a series of JAVA-based files that are received and run by a local virtual machine or other suitable middleware executed by control circuitry 704. In some of such embodiments (e.g., those employing MPEG-2, MPEG-4, HEVC or any other suitable digital media encoding schemes), the application may be, for example, encoded and transmitted in an MPEG-2 object carousel with the MPEG audio and video packets of a program.

FIG. 8 depicts an illustrative user equipment system, in accordance with some embodiments of this disclosure. In some embodiments, user equipment 807, 808, 810, 815 may be coupled to communication network 809. Communication network 809 may be one or more networks including the internet, a mobile phone network, mobile voice or data network (e.g., a 5G, 4G, or LTE network), cable network, public switched telephone network, or other types of communication network or combinations of communication networks. Paths (e.g., depicted as arrows connecting the respective devices to the communication network 809) may separately or together include one or more communications paths, such as a satellite path, a fiber-optic path, a cable path, a path that supports internet communications (e.g., IPTV), free-space connections (e.g., for broadcast or other wireless signals), or any other suitable wired or wireless communications path or combination of such paths. Communications with the user equipment may be provided by one or more of these communications paths but are shown as a single path in FIG. 8 to avoid overcomplicating the drawing.

Although communications paths are not drawn between user equipment, these devices may communicate directly with each other via communications paths as well as other short-range, point-to-point communications paths, such as USB cables, IEEE 1394 cables, wireless paths (e.g., Bluetooth, infrared, IEEE 702-11x, etc.), or other short-range communication via wired or wireless paths. The user equipment may also communicate with each other directly through an indirect path via communication network 809.

System 800 may comprise media content source 802, one or more servers 804, and/or one or more edge computing devices. In some embodiments, the application may be executed at one or more of control circuitry 811 of server 804 (and/or control circuitry of user equipment 807, 808, 810, 815 and/or control circuitry of one or more edge computing devices). In some embodiments, the media content source and/or server 804 may be configured to host or otherwise facilitate video communication sessions between user equipment 807, 808, 810, 815 and/or any other suitable user equipment, and/or host or otherwise be in communication (e.g., over communication network 809) with one or more social network services.

In some embodiments, server 804 may include control circuitry 811 and storage 814 (e.g., RAM, ROM, Hard Disk, Removable Disk, etc.). Storage 814 may store one or more databases. Non-transitory memory may store instructions that, when executed by control circuitry, I/O circuitry, any other suitable circuitry or combination thereof, executes functions of an application as described above. Server 804 may also include an I/O path 812. In some embodiments, I/O path 812 may be an I/O circuitry. I/O circuitry may be a NIC card, audio output device, mouse, keyboard card, any other suitable I/O circuitry device or combination thereof. I/O path 812 may provide video conferencing data, device information, or other data, over a local area network (LAN) or wide area network (WAN), and/or other content and data to control circuitry 811, which may include processing circuitry, and storage 814. Control circuitry 811 may be used to send and receive commands, requests, and other suitable data using I/O path 812, which may comprise I/O circuitry. I/O path 812 may connect control circuitry 811 to one or more communications paths.

Control circuitry 811 may be based on any suitable control circuitry such as one or more microprocessors, microcontrollers, digital signal processors, programmable logic devices, field-programmable gate arrays (FPGAs), application-specific integrated circuits (ASICs), etc., and may include a multi-core processor (e.g., dual-core, quad-core, hexa-core, or any suitable number of cores) or supercomputer. In some embodiments, control circuitry 811 may be distributed across multiple separate processors or processing units, for example, multiple of the same type of processing units (e.g., two Intel Core i7 processors) or multiple different processors (e.g., an Intel Core i6 processor and an Intel Core i7 processor). In some embodiments, control circuitry 811 executes instructions for an emulation system application stored in memory (e.g., the storage 814). Memory may be an electronic storage device provided as storage 814 that is part of control circuitry 811. Memory may store instructions to run the application.

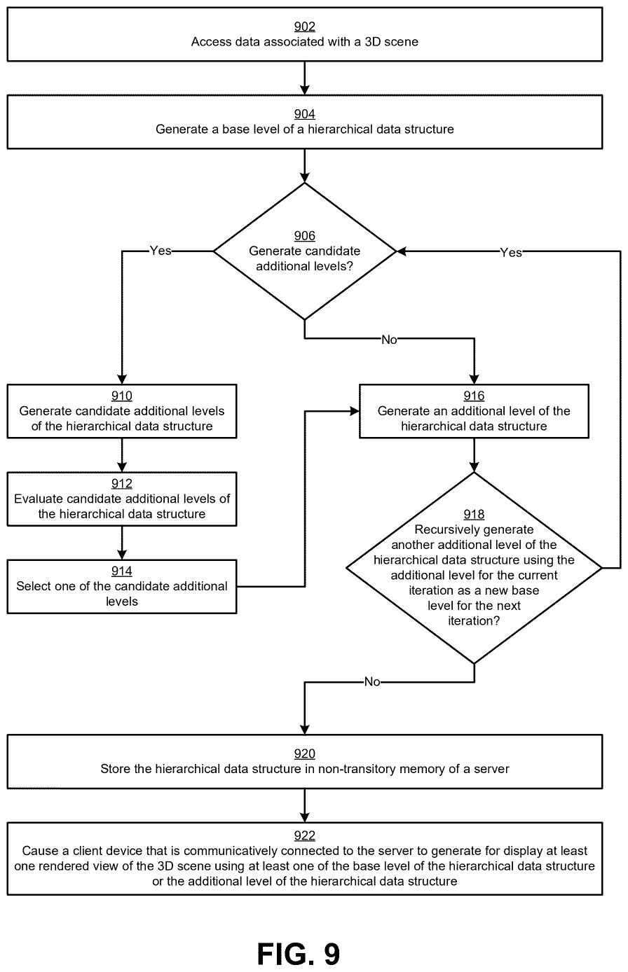

FIG. 9 depicts a flow diagram of a process for incorporating hierarchical precision in a 3D Gaussian Splatting model, in accordance with some embodiments of this disclosure.

In some embodiments, at 902, input/output circuitry (e.g., I/O circuitry 702 of FIG. 7, I/O circuitry 812 of FIG. 8) accesses data associated with a 3D scene (e.g., 3D scene data 103 of FIG. 1A). The data associated with the 3D scene may be 2D image data (e.g., one or more 2D images, photographs, rendered views of a 3D scene), 3D scene data (e.g., data comprising GSs, vertices, 3D object parameter), or any combination thereof.

In some embodiments, at 904, control circuitry (e.g., control circuitry 704 of FIG. 7, 811 of FIG. 8) generates a base level of a hierarchical data structure. For example, the base level of the hierarchical data structure may be base level 105 of FIG. 1A. In some embodiments, the base level of the hierarchical data structure of GSs may be generated using Gaussian pruning. In some embodiments, at 906, control circuitry (e.g., control circuitry 704 of FIG. 7, 811 of FIG. 8) determines whether to generate candidate additional levels. In response to determining to generate candidate additional levels, at 910, the control circuitry may generate, evaluate (e.g., based on outputs of a scene fidelity loss function), and select (e.g., based on the evaluation) candidate additional levels of the hierarchical data structure (e.g., first candidate level 107 of FIG. 1A, second candidate level 109 of FIG. 1B, third candidate level 111 of FIG. 1B). The candidate levels may be expected to result in substantially equal or similar memory footprints (e.g., configurations along an equal size line of FIG. 2). The selection of an additional level of the hierarchical data structure of GSs may be performed without the generation and evaluation of candidate levels, rendering steps 910 and 912 as optional. For example, the selection of the additional level may be performed based on a user input via a client device, an output of a computational model (e.g., a machine learning (ML) model), previous selections of additional levels, or any combination thereof.

The control circuitry, at 916, may generate an additional level of the hierarchical data structure. The generation of the additional level of the hierarchical data structure may be based on the selection of step 914. In some embodiments, the generation of the additional level of the hierarchical data structure is performed without generating, evaluating, and selecting candidate additional levels, rendering steps 910, 912, and 914 as optional.

In some embodiments, the control circuitry, at 918, determines whether to recursively generate another additional level of the hierarchical data structure using the additional level for the current iteration as a new base level for the next iteration. If the control circuitry determines to recursively generate another additional level of the hierarchical data structure, then the control circuitry may return to step 906, using the additional level for the current iteration as a new base level of the next iteration. For example, base level 105 of FIG. 1A may have been the additional level of a previous iteration of the recursion. As another example, the control circuitry may select the second candidate level 109 of FIG. 1B as the additional level of the hierarchical data structure during a current iteration of the recursion, and, in a next iteration of the recursion, the control circuitry may use the second candidate level 109 of FIG. 1B as a new base level.

In some embodiments, at 920, the input/output circuitry stores the hierarchical data structure. For example, the input/output circuitry may store the hierarchical data structure in non-transitory memory of server 101 of FIG. 1A.

In some embodiments, at 922, the control circuitry causes a client device that is communicatively connected to a server (e.g., server 101 of FIG. 1A) to render a view of the 3D scene (e.g., rendered view 113 of FIG. 1B) using the base level or the additional level of the hierarchical data structure. In some embodiments, a server (e.g., server 101 of FIG. 1A) renders the view of the 3D scene (e.g., rendered view 113 of FIG. 1B). The control circuitry may cause the client device to generate for display the rendered view of the 3D scene (e.g., rendered view 113 of FIG. 1B).

The processes discussed above are intended to be illustrative and not limiting. One skilled in the art would appreciate that the steps of the processes discussed herein may be omitted, modified, combined and/or rearranged, and any additional steps may be performed without departing from the scope of the invention. More generally, the above disclosure is meant to be illustrative and not limiting. Only the claims that follow are meant to set bounds as to what the present invention includes. Furthermore, it should be noted that the features described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted that the systems and/or methods described above may be applied to, or used in accordance with, other systems and/or methods.

1. A method comprising:
accessing data associated with a 3D scene;
generating a base level of a hierarchical data structure, wherein the base level comprises a first plurality of Gaussian Splats (GSs), wherein parameters for the first plurality of GSs are stored at a first bit depth;
generating an additional level of the hierarchical data structure, wherein the additional level comprises a second plurality of GSs, wherein parameters for the second plurality of GSs are stored at a second bit depth, wherein the second plurality of GSs comprises more GSs than the first plurality of GSs, or the second bit depth is greater than the first bit depth, and
wherein the second plurality of GSs comprises a subset of GSs that contains a number of GSs equal to a number of GSs in the first plurality of GSs, wherein respective parameters of each GS of the subset of GSs are based at least in part on respective parameters of a respective GS of the first plurality of GSs;
storing the hierarchical data structure in non-transitory memory of a server; and
causing a client device that is communicatively connected to the server to generate for display at least one rendered view of the 3D scene using at least one of the base level of the hierarchical data structure or the additional level of the hierarchical data structure.

2. The method of claim 1, further comprising:
transmitting the base level of the hierarchical data structure to the client device; and
causing the client device to generate for display the at least one rendered view of the 3D scene using the base level of the hierarchical data structure and refraining from using the additional level of the hierarchical data structure.

3. The method of claim 1, further comprising:
transmitting, to the client device, the base level of the hierarchical data structure and the additional level of the hierarchical data structure; and
causing the client device to generate for display the at least one rendered view of the 3D scene using the base level of the hierarchical data structure and refraining from using the additional level of the hierarchical data structure.

4. The method of claim 1, wherein the respective parameters of each GS of the subset of GSs comprises all bits of the respective parameters of each respective GS of the first plurality of GSs.

5. The method of claim 1, further comprising recursively generating another additional level of the hierarchical data structure by repeating the generating the additional level of the hierarchical data structure, wherein the additional level for a current iteration is used as a new base level for a next iteration.

6. The method of claim 1, further comprising:
evaluating a plurality of candidate additional levels of the hierarchical data structure, wherein each of the plurality of candidate additional levels is expected to result in substantially equal memory footprints, wherein the plurality of candidate additional levels comprises:
a first candidate level that comprises a first plurality of candidate GSs, wherein parameters for the first plurality of candidate GSs are stored at a first candidate bit depth, wherein the first candidate bit depth is greater than the first bit depth, wherein the first plurality of candidate GSs contains a number of GSs equal to the number of GSs in the first plurality of GSs,
a second candidate level that comprises a second plurality of candidate GSs, wherein parameters for the second plurality of candidate GSs are stored at a second candidate bit depth, wherein the second candidate bit depth is equal to the first bit depth, wherein the second plurality of candidate GSs comprises more GSs than the first plurality of GSs, and
a third candidate level that comprises a third plurality of candidate GSs, wherein parameters for the third plurality of candidate GSs are stored at a third candidate bit depth, wherein the third candidate bit depth is greater than the first bit depth, wherein the third plurality of candidate GSs comprises more GSs than the first plurality of GSs; and
selecting one of the plurality of candidate additional levels as the additional level based on the evaluating.

7. The method of claim 6, wherein the evaluating comprises:
determining a respective output of a scene fidelity loss function based on each of the plurality of candidate additional levels; and
comparing respective outputs of the scene fidelity loss function.

8. The method of claim 1, wherein:
the second plurality of GSs contains a number of GSs equal to the number of GSs in the first plurality of GSs, and
the second bit depth is greater than the first bit depth.

9. The method of claim 1, wherein:
the second bit depth is equal to the first depth, and
the second plurality of GSs comprises more GSs than the first plurality of GSs.

10. The method of claim 1, wherein:
the second plurality of GSs comprises more GSs than the first plurality of GSs, and
the second bit depth is greater than the first depth.

11. A system comprising:
input/output circuitry configured to:
access data associated with a 3D scene; and
control circuitry configured to:
generate a base level of a hierarchical data structure, wherein the base level comprises a first plurality of Gaussian Splats (GSs), wherein parameters for the first plurality of GSs are stored at a first bit depth;
generate an additional level of the hierarchical data structure, wherein the additional level comprises a second plurality of GSs, wherein parameters for the second plurality of GSs are stored at a second bit depth, wherein the second plurality of GSs comprises more GSs than the first plurality of GSs, or the second bit depth is greater than the first bit depth, and
wherein the second plurality of GSs comprises a subset of GSs that contains a number of GSs equal to a number of GSs in the first plurality of GSs, wherein respective parameters of each GS of the subset of GSs are based at least in part on respective parameters of a respective GS of the first plurality of GSs; and
store the hierarchical data structure in non-transitory memory of a server;
wherein the input/output circuitry is further configured to:
cause a client device that is communicatively connected to the server to generate for display at least one rendered view of the 3D scene using at least one of the base level of the hierarchical data structure or the additional level of the hierarchical data structure.

12. The system of claim 11, wherein:
the control circuitry is further configured to:
transmit the base level of the hierarchical data structure to the client device; and
the input/output circuitry is further configure to:
cause the client device to generate for display the at least one rendered view of the 3D scene using the base level of the hierarchical data structure and refraining from using the additional level of the hierarchical data structure.

13. The system of claim 11, wherein:
the control circuitry is further configured to:
transmit, to the client device, the base level of the hierarchical data structure and the additional level of the hierarchical data structure; and
the input/output circuitry is further configured to:
cause the client device to generate for display the at least one rendered view of the 3D scene using the base level of the hierarchical data structure and refraining from using the additional level of the hierarchical data structure.

14. The system of claim 11, wherein the respective parameters of each GS of the subset of GSs comprises all bits of the respective parameters of each respective GS of the first plurality of GSs.

15. The system of claim 11, wherein the control circuitry is further configured to:
recursively generate another additional level of the hierarchical data structure by repeating the generating the additional level of the hierarchical data structure, wherein the additional level for a current iteration is used as a new base level for a next iteration.

16. The system of claim 11, wherein the control circuitry is further configured to:
evaluate a plurality of candidate additional levels of the hierarchical data structure, wherein each of the plurality of candidate additional levels is expected to result in substantially equal memory footprints, wherein the plurality of candidate additional levels comprises:
a first candidate level that comprises a first plurality of candidate GSs, wherein parameters for the first plurality of candidate GSs are stored at a first candidate bit depth, wherein the first candidate bit depth is greater than the first bit depth, wherein the first plurality of candidate GSs contains a number of GSs equal to the number of GSs in the first plurality of GSs,
a second candidate level that comprises a second plurality of candidate GSs, wherein parameters for the second plurality of candidate GSs are stored at a second candidate bit depth, wherein the second candidate bit depth is equal to the first bit depth, wherein the second plurality of candidate GSs comprises more GSs than the first plurality of GSs, and
a third candidate level that comprises a third plurality of candidate GSs, wherein parameters for the third plurality of candidate GSs are stored at a third candidate bit depth, wherein the third candidate bit depth is greater than the first bit depth, wherein the third plurality of candidate GSs comprises more GSs than the first plurality of GSs; and
select one of the plurality of candidate additional levels as the additional level based on the evaluating.

17. The system of claim 16, wherein the evaluating comprises:
determining a respective output of a scene fidelity loss function based on each of the plurality of candidate additional levels; and
comparing respective outputs of the scene fidelity loss function.

18. The system of claim 11, wherein:
the second plurality of GSs contains a number of GSs equal to the number of GSs in the first plurality of GSs, and
the second bit depth is greater than the first bit depth.

19. The system of claim 11, wherein:
the second bit depth is equal to the first depth, and
the second plurality of GSs comprises more GSs than the first plurality of GSs.

20. The system of claim 11, wherein:
the second plurality of GSs comprises more GSs than the first plurality of GSs, and
the second bit depth is greater than the first depth.

21-50. (canceled)
